(19) United States
(12) Patent Application Publication
(10) Pub. No.: US 2002/0000803 A1
(43) Pub. Date: Jan. 3, 2002

(54) COF autohandler

(76) Inventor: Mitsuhiro Furuta, Tokyo (JP)

Correspondence Address: FLYNN, THIEL, BOUTELL & TANIS, P.C., 2026 Ramblind Road, Kalamazoo, MI, 49008-1699, US

(21) Appl. No.: 09/888,886

(22) Filed: Jun. 25, 2001

(30) Foreign Application Priority Data
Jun. 28, 2000 (JP) 2000-195212

(51) Int. Cl. G01R 1/00

(52) U.S. Cl. 324/158.1

(57) ABSTRACT

A COF autohandler capable of transporting a COF tape and comprising guide members for transporting the COF tape at the back face serving as an entire guide mechanism and rotary rollers each having a sprocket-like shape serving as a guide member for guiding the COF tape at the front face where a pattern is formed. Cylindrical support sections are provided to fill up an interior of sub-sprockets, pulleys and the main sprockets so that the COF tape 11 is prevented from falling in a gap between the cylindrical support sections. Rotary rollers each having a sprocket-like shape are provided on the tensioners to prevent the COF tape from falling in the gap.

### BACKGROUND OF THE INVENTION

1. Field of the Invention

The invention relates to a chip on film (COF) autohandler for inspecting and screening integrated circuits (ICs) on a COF tape.

2. Related Art

A tape automated bond (TAB) autohandler is well known by Japanese Patent Laid-Open Publication No. 7-239366 and the like. The well known TAB autohandler is first described. FIG. 4 shows a schematic view showing the conventional TAB autohandler, and FIGS. 5(A, B, C) are views showing a sprocket (pulley) and a tensioner.

As shown in FIGS. 4 and 5, the conventional TAB autohandler 30 is a device for inspecting and classifying an IC chip 31 on a TAB tape 33 which is formed of a film 32 made of polyimide and the like having a pattern 34 at a first face and the IC chip 31 such as a semiconductor chip and the like at the other face which is bonded and connected to the pattern 34. FIG. 5(B) exaggeratedly displays the pattern 34 of the TAB tape 33.

As shown in FIG. 4, the TAB autohandler 30 comprises a supply reel 2a and an receive real 2b, and the TAB tape 33 is wound around the supply reel 2a and receive real 2b. The TAB tape 33 wound around the supply reel 2a and receive real 2b is held by a supply side sub-sprocket 21a, a receive side sub-sprocket 21b, a supply side pulley 22a, a receive side pulley 22b, a supply side tensioner 23a, a receive side tensioner 23b, a supply side main sprocket 24a, a receive side main sprocket 24b and the like.

A pusher 3 is provided between the main sprockets 24a, 24b, and it grips the TAB tape 33 held between the main sprockets 24a, 24b together with the main sprockets 24a, 24b and also it is driven to freely push down and pull up the TAB tape 33 in the direction of the arrows A, B in FIG. 4. The tensioners 23a, 23b are provided for preventing the TAB tape 33 from slacking when the TAB tape 33 is pushed down and pulled up by the pusher 3. When the TAB tape 33 is pressed by the tensioners 23a, 23b at a given pressure, the tension of the TAB tape 33 is maintained.

The TAB tape 33 wound around the reels 2a, 2b is sequentially transported in the direction of the arrow T in FIG. 4, and the TAB tape 33 which is transported at the position of the pusher 3 is pushed down by the pusher 3 in the direction of the arrow A in FIG. 4 when the pusher 3 is driven and pushed. The IC chip 31 on the thus pushed down TAB tape 33 is brought into contact with a probe on a probe card and is energizable. Since the probe card, not shown, is connected to an IC tester, not shown, the IC chip 31 is inspected by the IC tester in electric characteristics.

A classifying unit, not shown, is disposed at the downstream side of the pusher 3 for classifying the IC chip 31 on the TAB tape 33 to into a defective one or non-defective one on the bases of the inspection result by the IC tester.

The sub-sprocket 21a, the pulley 22a and the main sprocket 24a are respectively constructed, as shown in FIG. 5(A), such that they guide and support the face of the TAB tape 33 at the side of the IC chip 31, in view of the construction thereof, while they have cylindrical guide faces 5 for guiding and supporting the TAB tape 33. A groove 15 is provided on the guide faces 5 at the portion in the neighborhood of the center thereof in a width direction corresponding to the mounting area of the IC chip 31. In the case of the sub-sprocket 21a, the main sprocket 24a, teeth for engaging with a perforation holes of the TAB tape 33, not shown, are provided on the guide faces 5.

On the other hand, the tensioner 23a presses the TAB tape 33 at the side of the pattern 34 as shown in FIGS. 5(B) and 5(C), and it has contact faces 6 for pressing the TAB tape 33. A groove 16 is provided at the portion in the neighborhood of the center between the contact faces 6 in a width direction corresponding to a formation area of the pattern 34. The constituents of the TAB autohandler 30 are disposed line-symmetrically with respect to the center of the pusher 3, and hence the explanation of the constituents at the right side of FIG. 4 is omitted.

Meanwhile, it is known that a COF is used by an IC for driving a liquid crystal display instead of the TAB. FIG. 6 is a view showing the COF tape. The mounting of an IC chip on a film is common to the COF and the TAB. That is, the COF tape 11 has a pattern 1A formed of leads on a film 12 as shown in FIG. 6, wherein an IC chip 1B is mounted relative to the pattern 1A. Depicted by 1C shown in FIG. 6 is a test pad, 1D is a resist provided on the pattern 1a, and 1E is perforation holes for engaging with a sprocket and the like.

The COF tape has the following three characteristics which are different from the characteristics of a TAB.

1. The thickness of a film is thin, i.e., not more than 40 μm (not less than 75 μm in the conventional TAB).

2. A mounting face of an IC chip and a forming face of a pattern are the same (it is the mainstream in the conventional TAB that an IC chip is mounted on the pattern from the back face thereof).

3. There is no window for bending purpose, and hence there is no electrical short circuit at the back face (there is a window for bending purpose in the conventional TAB).

The COF tape comprising the foregoing COF is similar to the TAB tape in a configuration. Accordingly, when inspecting and screening an IC chip on a COF tape, it has been considered that a device similar to the foregoing TAB autohandler may be used.

As is explained in the characteristics of the foregoing COF, in the case of the COF, the thickness of the film 12 is thin and soft compared with the TAB in reality, so that when a tension is applied to the COF tape 11 by the tensioners 23a, 23b, there is a possibility that the COF tape 11 falls in the groove 16 (see FIG. 5(B)) of contact faces 6 of the tensioners 23a, 23b, the COF tape 11 falls in the groove 15 (see FIG. 5(A)) between the guide faces 5 of the pulleys 22a, 22b, or feed holes 1E of the COF tape 11 are damaged when engaging with the sprockets 21a, 21b or main sprockets 24a, 24b, and hence a stable transportation is not secured.

### SUMMARY OF THE INVENTION

The invention has been developed in the foregoing circumstances, and it is an object of the invention to provide a COF autohandler capable of inspecting and screening an IC chip on a COF tape, and also capable stably transporting the COF tape.

To achieve the above objects, the COF autohandler according to a first aspects of the invention comprises, as shown in FIG. 1, transportation means 2C-2K for transporting a COF tape 11 having a pattern 1A and an IC chip 1B on a first face of a tape member 12, and inspection means 3 for sequentially inspecting the IC chip 1B on the COF tape 11 transported by the transportation means 2C-2K, characterized in that the transportation means 2C-2K comprises transportation rotary bodies 2C-2F, 2J, 2K for guiding and supporting the COF tape 11, and each of the transportation rotary bodies 2C-2F, 2J, 2K has a cylindrical support face 25 which contacts a second face opposite to the first face of the tape member 12 and supports the COF tape 11 to prevent the COF tape 11 from falling in a gap W.

The COF autohandler according to a second aspect of the invention is characterized in that the transportation rotary bodies 2C-2F, 2J, 2K of the first aspect of the invention comprises two split pieces 70 each comprising flange sections 80, 80 and cylindrical support section 81, 81, and wherein the cylindrical support sections 81, 81 of the split pieces 70 contact each other or approach to each other to form the support face 25.

The COF autohandler according to the third aspects of the invention comprises transportation means 2C-2K for transporting a COF tape 11 having a pattern 1A and an IC chip 1B on a first face of a tape member 12, and inspection means for sequentially inspecting the IC chip 1B on the COF tape 11 transported by the transportation means 2C-2K, characterized in that the transportation means 2C-2K have tape tension holding means 2G, 2H, and the tape tension holding means 2G, 2H have a pair of press rotary bodies 95 which are freely rotatable and contact the first face of the COF tape 11, and a contact prevention gap 98 provided between the press rotary bodies or small sprockets 95 corresponding to the position of the pattern 1A and IC chip 1B provided on the first face.

The COF autohandler according to the fourth aspect of the invention is characteristics in that press rotary bodies 95 of the third aspect of the invention have teeth 96 engageable with the tape member 12.

The COF autohandler according to the fifth aspects of the invention is characteristics in that the transportation means 2C-2K of the third or fourth aspect of the invention have transportation rotary bodies 2C-2F, 2J, 2K of the first or second aspect of the invention.

With the foregoing construction, even if a strong tension is applied to the transportation rotary bodies 2C-2F, 2J, 2K, the COF tape 11 is supported by the cylindrical support face 25.

Since the rotating press rotary bodies 95 contact and press the COF tape 11 at the tape tension holding means 2G, 2H, a load applied to the COF tape 11 is reduced.

Reference numerals are given to each constituent corresponding to each constituent in the figures for the convenience's sake, and hence the invention is not limited to the reference numerals depicted in the drawings.

### BRIEF DESCRIPTION OF THE DRAWINGS

FIG. 1 is a schematic view showing a COF autohandler according to a preferred embodiment of the invention.

FIG. 2 is a view showing a sprocket (pulley).

FIG. 3 is a view showing a tensioner.

FIG. 4 is a schematic view showing a conventional TAB autohandler.

FIG. 5 is a view showing a sprocket (pulley) and a tensioner in FIG. 4.

FIG. 6 is a view showing a COF tape as well as a TAB tape.

### PREFERRED EMBODIMENT OF THE INVENTION

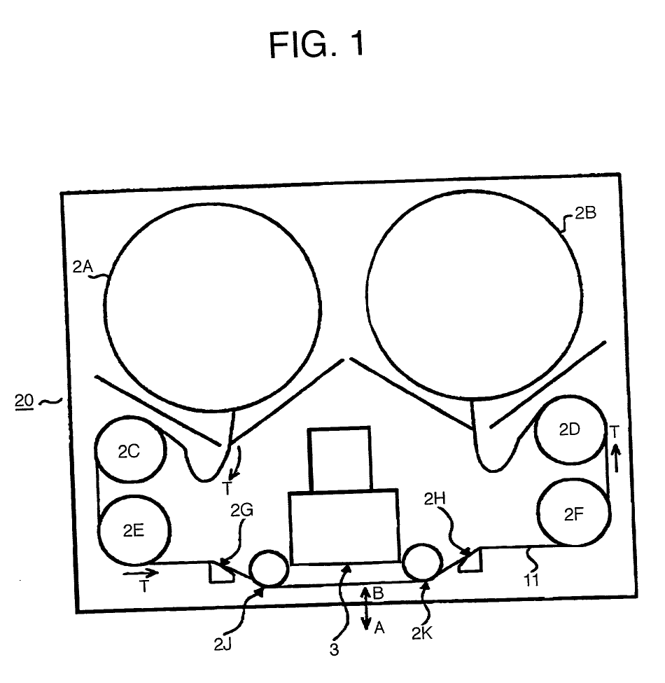

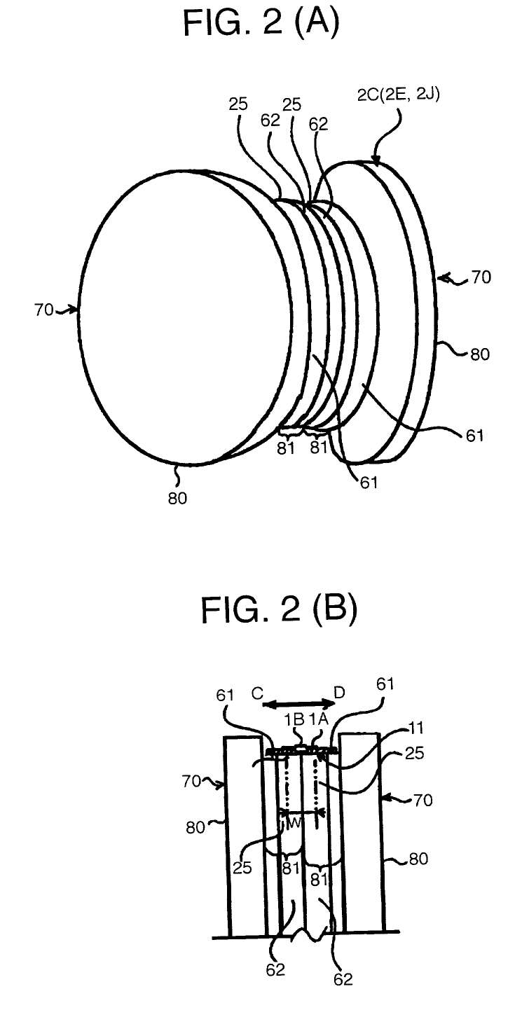

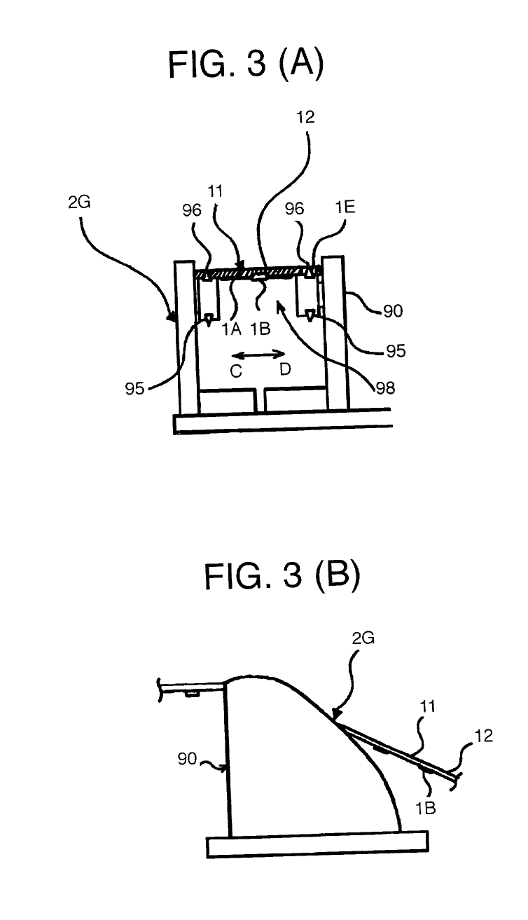

A COF autohandler according to a preferred embodiment of the invention is now described with reference to FIGS. 1 to 3. FIG. 1 is a schematic view showing a COF autohandler according to a preferred embodiment of the invention, FIG. 2 is a view showing a sprocket (pulley) and FIG. 3 is a view showing a tensioner.

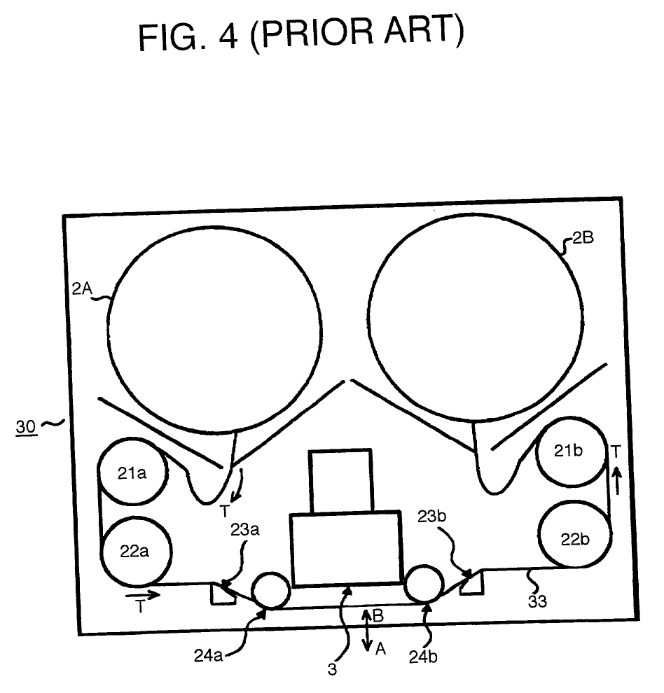

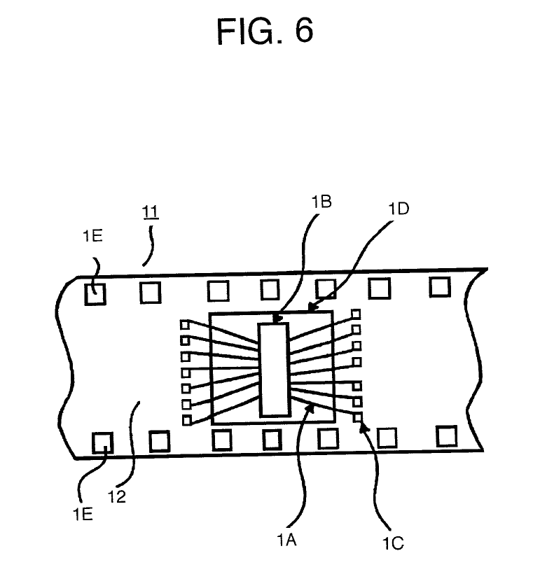

A COF autohandler 20 of the invention is substantially the same construction as the conventional TAB autohandler 30 shown in FIG. 4. Components of the COF autohandler 20 which are the same in construction and function as those of the TAB autohandler 30 and are denoted by the same reference numerals. A COF tape 11 is the same as that shown in FIG. 6.

That is, the COF autohandler 20 has, as shown in FIG. 1, a supply reel 2A and an receive real 2B wherein the COF tape 11 is wound around the reels 2A, 2B. The COF tape 11 wound around the reels 2A, 2B is held by a supply side sub-sprocket 2C, a receive side sub-sprocket 2D, a supply side pulley 2E, an receive side pulley 2F, a supply side tensioner 2G, an receive side tensioner 2H, a supply side main sprocket 2J, an receive side main sprocket 2K and the like.

A pusher 3 is provided between the main sprockets 2J, 2K and it grips the COF tape 11 held between the main sprockets 2J, 2K together with the main sprockets 2J, 2K and freely pushes down and pulls up the COF tape 11 in the direction of the arrows A, B in FIG. 1.

The COF tape 11 extended between the reels 2A, 2B is sequentially transported in the direction of the arrow T in FIG. 1, wherein the COF tape 11 transported to the position of the pusher 3 is pushed down toward the arrow A in FIG. 1 by the driving motion of the pusher 3 to push down the COF tape 11. The IC chip 1B on the pushed down COF tape 11 is brought into contact with a probe card, not shown, and rendered conductive, and the IC chip 1B is inspected by an IC tester connected to the probe card, not shown.

A classifying unit and the like are disposed at the down stream side of the pusher 3 for classifying the IC chip 1B on the COF tape 11 into a defective one or non-defective one on the basis of the inspection result by the IC tester.

The difference between the COF autohandler 20 of the invention and the conventional TAB autohandler 30 is described. Respective sprockets 2C, 2D, 2J, 2K, and the pulleys 2E, 2F of the COF autohandler 20 have a pair of discoid flange sections 80, 80, and guide sections 61, 61 each having a small diameter and discoid shape are provided concentrically with and between the flange sections 80, 80, to face each other at one side of the flange sections 80, 80. The construction of the flange sections 80, 80 and the guide sections 61, 61 are the same as those of the prior art. The sprocket 2C is exemplified in FIGS. 2(A), (B).

Inner guide sections 62, 62 each having the same diameter and discoid shape as the guide sections 61, 61 are provided at concentrically with and between the guide sections 61, 61 to face each other at one side of the guide sections 61, 61. Respective pairs of flange sections 80, 80, guide sections 61, 61, and inner guide sections 62, 62 constitute split pieces 70, 70. That is, respective sprockets 2C, 2D, 2J, 2K and the pulleys 2E, 2F are constituted by a pair of split pieces 70, 70.

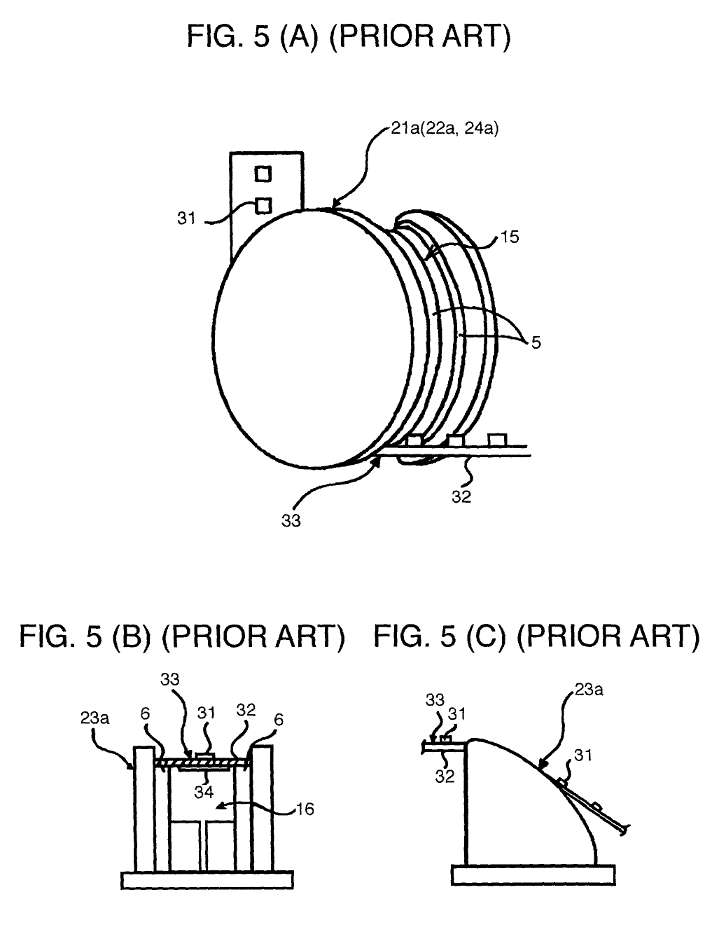

The guide section 61, 61 and the inner guide sections 62, 62 have the same diameter and discoid shape are disposed concentrically with and adjacent to each other in the central axial direction in the respective split pieces 70, 70, and they constitute one cylindrical support sections 81, 81 as a whole. Outer peripheral faces of the cylindrical support sections 81, 81 constitute a support face 25. The cylindrical support sections 81, 81 basically contact each other, which is considered that the groove 15 (see FIG. 5(A)) in the respective sprocket 21a, 21b, 24a, 24b and the pulleys 22a, 22b of the conventional COF autohandler is filled up by the inner guide sections 62, 62.

In the case of the sub-sprocket 2C, 2D and main sprocket 2J, 2K, teeth, not shown, are provided in the guide sections 61, 61 to be engaged with the feed holes 1E of the COF tape 11 (see FIG. 6).

With the foregoing construction, even if a tension is applied to the COF tape 11 by the tensioners 2G, 2H, since the COF tape 11 is guided and supported by the support face 25 over the entire length in the width direction thereof in the sprockets 2C, 2D, 2J, 2K and the pulleys 2E, 2F, even if an excessive force applied to the feed holes 1E of the COF tape 11, the COF tape 11 can be safely transported while the feed holes 1E are not damaged or the COF tape 11 does not fall in a gap.

The IC chip 1B is mounted on the COF tape 11 at a first face on which the pattern 1A is provided as shown in FIG. 2(A), and the contact between the COF tape 11 and the sprockets 2C, 2D, 2J, 2K and the pulleys 2E, 2F is effected at a second face where the pattern 1A and IC chip 1B are not present. Accordingly, it is convenient that both the pattern 1A and the IC chip 1B are not damaged even if the COF tape 11 contact the support face 25.

The split pieces 70, 70, namely, the cylindrical support sections 81, 81 may be approached to or moved away from each other in the direction of the arrows C, D shown in FIG. 2(B) so that the sprockets 2C, 2D, 2J, 2K and the pulleys 2E, 2F can cope with the COF tape 11 having the various widths (e.g., 35 mm or 48 mm). For example, when the cylindrical support sections 81, 81 are moved away from each other, a gap W depicted by two dotted and one chain line is formed between the cylindrical support sections 81, 81 as shown in FIG. 2(B), but the cylindrical support sections 81, 81 are close to each other while a width of the gap W (e.g., 13 mm) is sufficiently small compared with a contact area relative to the COF tape 11, and hence the COF tape 11 does not fall in the gap W.

Another difference between the COF autohandler 20 of the invention and the TAB autohandler 30 is described next. That is, the tensioner 2G of the COF autohandler 20 has a pair of plate-like bodies 90 as shown in FIG. 3 but the bodies 90 have no guide faces 6 (see FIG. 5(B)) which are described in the Related Art. The bodies 90 have a pair of opposite rotary rollers 95 which are freely rotatable and positioned at positions where portions close to both ends of the COF tape 11 in width direction are brought into contact with the bodies 90 as shown in FIG. 3(A).

That is, the COF tape 11 contacts the outer peripheries of the rotary rollers 95, 95 at the tensioner 2G. Teeth 96 are formed on the outer peripheries of the rotary rollers 95, 95, and the teeth 96 engage with the feed holes 1E of the COF tape 11. Although the pattern 1A and the IC chip 1B of the COF tape 11 are respectively directed inward of the tensioner 2G (lower side in FIG. 3 on the paper), since the contact prevention gap 98 is formed between the rotary rollers 95, 95 in the position corresponding to the pattern 1A and IC chip 1B, the pattern 1A and the IC chip 1B do not contact anything, and hence they are not damaged. The tensioner 2H is disposed line symmetrically with respect to the tensioner 2G.

Even if the COF tape 11 is pushed down or pulled up by the tensioners 2G, 2H, it is prevented from falling in the gap because it is engaged with the rotary rollers 95. That is, since the COF tape 11 does not fall in the contact prevention gap 98 between the rotary rollers 95, the COF tape 11 can be safely transported. Further, a load to be applied to the COF tape 11 which is caused by the rotation of the rotary rollers 95 is reduced as much as possible. The reduction of the load has an effect that the COF tape 11 does not fall in the gap, and the damage of the COF tape 11 in the feed holes 1E is effectively prevented.

The rotary rollers 95, 95 may be freely approached to or moved away from each other in the direction of the arrow C, D in FIG. 3(A) so as to cope with the COF tape 11 having various widths.

The number of sprockets 2C, 2D, 2J, 2K and pulleys 2E, 2F and tensioners 2G, 2H is not limited to those set forth in the preferred embodiment but can be set at an arbitrary number.

According to the COF autohandler of the first aspects of the invention, even if a strong tension is applied to the COF tape in the transportation rotary bodies, the COF tape is supported by the cylindrical support face so that the COF tape does not fall in a gap. Further, it is possible to prevent an excessive force from applying to the feed holes, and the like so that the feed holes and the like are prevented from being damaged. Accordingly, it is possible to safely transport the COF tape according to the invention.

According to the COF autohandler of the second aspect of the invention, it is convenient because two split pieces can cope with the COF tape having various widths.

According to the COF autohandler of the third aspect of the invention, the rotating press rotary bodies brought into contact with the COF tape to press the COF tape in the tape tension holding means, so that a load applied to the COF tape is reduced, and the COF tape is prevented from falling in a gap or it is prevented from being damaged, and hence the COF tape can be safely transported.

According to the COF autohandler of the fourth aspect of the invention, since the teeth of the press rotary bodies engage with the tape member, the COF tape is not deviated in position and hence it is possible to prevent the COF tape from falling in a gap with assurance.

According to the COF autohandler of the fifth aspect of the invention, it is possible to realize an effective COF autohandler capable of preventing the COF tape from falling in a gap or from being damaged over the entire transportation means.

What is claimed is:

1. A COF autohandler comprising:
transportation means for transporting a COF tape having a pattern and an IC chip on a first face of a tape member; and
inspection means for sequentially inspecting the IC chip on the COF tape transported by the transportation means;
wherein the transportation means comprises transportation rotary bodies for guiding and supporting the COF tape, and each of the transportation rotary bodies has a cylindrical support face which contacts a second face opposite to the first face of the tape member and supports the COF tape to prevent the COF tape from falling in a gap.

2. The COF autohandler according to claim 1, wherein the transportation rotary bodies comprises two split pieces each comprising flange sections and cylindrical support section, and wherein the cylindrical support sections of the split pieces contact each other or approach to each other to form the support face.

3. A COF autohandler comprising:
transportation means for transporting a COF tape having a pattern and an IC chip on a first face of a tape member; and
inspection means for sequentially inspecting the IC chip on the COF tape transported by the transportation means;
wherein the transportation means have tape tension holding means, and the tape tension holding means have a pair of press rotary bodies which are freely rotatable and contact the first face of the COF tape, and a contact prevention gap provided between the press rotary bodies corresponding to the position of the pattern and IC chip provided on the first face.

4. The COF autohandler according to claim 3, wherein the press rotary bodies have teeth engageable with the tape member.

5. The COF autohandler according to claim 3, wherein the transportation means have transportation rotary bodies.
